(19) United States
(12) Patent Application Publication
(10) Pub. No.: US 2007/0281084 A1
(43) Pub. Date: Dec. 6, 2007

(54) Apparatus and method for depositing layer on substrate

(75) Inventors: Atsuhiko Hirosawa, Hiratsuka-shi (JP); Noboru Iida, Hiratsuka-shi (JP); Norihiko Sato, Hiratsuka-shi (JP); Atsushi Nagato, Hiratsuka-shi (JP); Toshiyuki Kamei, Hiratsuka-shi (JP); Kouichi Nishikido, Tokyo (JP); Motonori Nakamura, Tokyo (JP)

Correspondence Address: JOSEPH P. FARRAR, ORION CONSULTING, LTD., KANDA CENTER BLDG., 5F 2-3-2 KAJCHO, CHIYODA-KU, TOKYO, 101-0044, omitted

(73) Assignee: SUMCO TECHXIV CORPORATION, Tokyo (JP)

(21) Appl. No.: 11/806,091

(22) Filed: May 30, 2007

(30) Foreign Application Priority Data
May 31, 2006 (JP) 2006-151356
May 31, 2006 (JP) 2006-151374

(51) Int. Cl. C23C 16/00; B05C 11/00

(52) U.S. Cl. 427/248.1; 118/715; 118/665

(57) ABSTRACT

A reactant gas is supplied to a gas inlet port 40B of a reaction chamber 20A from a plurality of gas flow paths 36A. The number of gas flow paths 36A is five or more within a range of one side of the gas inlet port 40B divided in two at the center thereof. The pitch between adjacent gas flow paths 36A is 10 mm or more. A baffle 38 having a plurality of slit holes 38A is disposed upstream of the gas flow paths 36A. The gas flow rates of the respective gas flow paths 36A are adjusted by recurrent calculation using layer growth sensitivity data that defines the relation between the gas flow rates of the respective gas flow paths 36A.

### CROSS-REFERENCE TO RELATED APPLICATIONS

This application relates to and claims priority rights from Japanese Patent Application No. 2006-151356 and No. 2006-151374, both filed on May 31, 2006, the entire disclosures of which are hereby incorporated herein by reference.

### BACKGROUND OF THE INVENTION

1. Field of the Invention

The present invention relates to an apparatus and method for depositing a film or a layer such as an epitaxial layer on the surface of a substrate such as a semiconductor wafer.

2. Description of the Related Art

Japanese Patent No. 2641351 (JP-2641351-B) discloses a wafer processing reactor for vapor deposition of a silicon layer on the surface of a wafer. In such wafer processing reactor, an array of lamps is disposed at a top and a bottom of a reaction chamber, a rotating wafer pedestal is disposed horizontally at the center of the reaction chamber, and a gas inlet port and a gas exhaust port are provided on diametrically opposite sides of the wafer processing reactor across a wafer. In the layer deposition process, the lamp arrays heat the entire reaction chamber, the wafer pedestal rotates the wafer, and one or more reactant gasses flow from the gas inlet port, across the wafer, and to the gas exhaust port.

In the conventional apparatus described above, the concentration of the reactant gas diminishes the further downstream the flow, and consequently the speed of deposition of a layer on the wafer declines the further downstream the flow. To diminish the effect of this decline in layer deposition speed the wafer is usually rotated during the layer deposition process. As a result, the distribution of the layer on the wafer, that is, the thickness of the layer, becomes uneven (either thinner or thicker) as the reactant gas is consumed. At the same time, one of the most important quality requirements of wafer products is uniformity of layer thickness distribution across the entire wafer. Accordingly, in order to compensate for the tendency of the layer distribution to thin or thicken, it is possible to make the layer thickness distribution more uniform by controlling the gas flow rate across the gas inlet port so that the center either thins or thickens compared to the edges.

As semiconductor IC circuit elements continue to shrink in size, the precision of thickness uniformity required of epitaxial and other surface layers on the wafer becomes increasingly important. In the conventional apparatus described above, the gas inlet port is divided into seven gas transport channels, for example, and by varying the gas flow rates in those seven gas transport channels the gas flow rate distribution can be controlled. However, no matter how the gas flow rates of the seven gas transport channels are adjusted there is a limit to the precision of the layer thickness distribution that can be achieved thereby, and it becomes difficult to satisfy the ever more demanding requirement for layer thickness uniformity. As one approach, the number of gas transport channels inside the gas inlet port can be increased to greater than seven. However, if there are too many gas transport channels, a different problem like the following occurs, possibly making uniform layer thickness distribution not less but more difficult.

Specifically, when the number of gas transport channels inside the gas inlet port is increased, the number of vertical vanes cutting across the gas inlet port also increases and the pitch between adjacent gas transport channels (that is, the distance between the centers of the gas transport channels) decreases. As a result, the effect of diminished gas flow velocity due to the vertical vanes becomes markedly apparent through the gas flow rate distribution, with the gas flow rate distribution assuming a saw-tooth- or comb-tooth-shaped distribution, for example, and losing smoothness, which makes uniform layer thickness distribution even more difficult to achieve.

In addition, to make the layer thickness distribution on the wafer uniform, a control technology for how to control the gas flow rate distribution across the gas inlet port is indispensable. However, although in JP-2641351-B there is a detailed disclosure of the mechanical structure of the wafer processing reactor, there is no specific disclosure of a specific gas flow rate distribution control technology.

### SUMMARY OF THE INVENTION

The object of the present invention is to improve layer thickness distribution control when depositing a film or a layer such as an epitaxial layer on the surface of a substrate such as a semiconductor wafer.

According to a first aspect of the present invention, a reactor for depositing a layer on a substrate, comprises a reaction device having a reaction chamber in which the substrate is placed; a gas inlet port provided on the reaction device extending over a predetermined range in a widthwise direction along a periphery of the substrate placed inside the reaction chamber for introducing a reactant gas into the reaction chamber; a plurality of gas flow paths arrayed widthwise on an upstream side of the gas inlet port that communicate with the gas inlet port, each supplying the reactant gas to the gas inlet port at respective gas flow rates; and a gas flow control device configured to control the respective gas flow rates of the plurality of gas flow paths. The gas flow paths number at least five within a range of one side of the gas inlet port divided in two at the center of the widthwise direction of the predetermined range of the gas inlet port, and a pitch between adjacent gas flow paths is 10 mm or more.

Such a structure improves gas flow velocity distribution control in the widthwise direction of the gas inlet port 20B, thus improving the precision of layer thickness distribution uniformity.

Preferably, the pitch between adjacent gas flow paths ranges from substantially 12 mm to substantially 18 mm. Alternatively, preferably, a difference between a fastest gas flow velocity and a slowest gas flow velocity immediately after exiting the gas inlet port in a range in the widthwise direction of 1 pitch between adjacent gas flow paths is substantially 0.5 m/sec or less. Alternatively, preferably, the number of gas flow paths is at least eight in the range of one side of the gas inlet port when the substrate measures substantially 200 mm in the widthwise direction thereof. Alternatively, preferably, the number of gas flow paths is at least 12 in the range of one side of the gas inlet port when the substrate measures substantially 300 mm in the widthwise direction thereof.

Further, the reactor may further comprise a flow velocity equalizer configured to equalize a gas flow velocity distribution in the widthwise direction within each of the plurality of gas flow paths, thus further improving the precision of layer thickness distribution uniformity. In a preferred embodiment, the flow velocity equalizer has a plurality of flow rectifying holes that respectively communicate with the plurality of gas flow paths, with the flow rectifying holes comprising long, narrow slits extending in the widthwise direction.

Further, the reactor may comprise a blade unit disposed inside the gas inlet port having a plurality of blades for forming a plurality of gas transport channels that respectively communicate with the plurality of gas flow paths. Preferably, the blade unit comprises a separate component detachable from a component that forms walls of the gas inlet port. Further, a gas flow adjustor unit may be provided in a gas transport channel located at the center of the blade unit in the widthwise direction thereof for bending gas flows toward the center of the widthwise direction.

According to another aspect of the present invention, a reactor for depositing a layer on a substrate comprises a reaction device having a reaction chamber in which the substrate is placed; a rotation device that rotates the substrate inside the reaction chamber; a gas inlet port provided on the reaction device extending over a predetermined range in a widthwise direction along a periphery of the substrate placed inside the reaction chamber for introducing a reactant gas into the reaction chamber; a plurality of gas flow paths arrayed widthwise on an upstream side of the gas inlet port that communicate with the gas inlet port, each supplying the reactant gas to the gas inlet port at respective gas flow rates; and a gas flow control device configured to control the respective gas flow rates of the plurality of gas flow paths. The gas flow control device has a first flow rate adjustment means configured to adjust the respective gas flow rates of the plurality of gas flow paths by inputting first layer thickness data indicating a thickness of a first layer previously deposited by rotation on a first substrate while rotating the first substrate inside the reaction chamber, obtaining a deviation between layer growth rates at various locations on the first substrate and a predetermined target layer growth rate based on the first layer thickness data, and using predetermined layer growth sensitivity data that defines a sensitivity to a change in layer growth rate distribution on the substrate caused by a change in the respective gas flow rates of the plurality of gas flow paths to reduce the deviation between the layer growth rates at the various locations on the first substrate and the target layer growth rate.

In a preferred embodiment, the gas flow control device further comprises a second flow rate adjustment means configured to adjust the respective gas flow rates of the plurality of gas flow paths by inputting second layer thickness data indicating a thickness of a second layer previously deposited by rotation on a second substrate while rotating the second substrate inside the reaction chamber and obtain a convexity slope of the layer thickness distribution on the second substrate to reduce the convexity slope to substantially zero. Then, after the second flow rate adjustment means performs gross adjustment of the gas flow rates, the first flow rate adjustment means inputs the first layer thickness data obtained from results of the first layer previously deposited by rotation applying the gas flow rate as adjusted by the second flow rate adjustment means and further performs fine adjustment of the gas flow rates based on the first layer thickness data.

Additionally, in a preferred embodiment, the gas flow control device further comprises a third flow rate adjustment means configured to adjust the respective gas flow rates of the plurality of gas flow paths by inputting third layer thickness data indicating a thickness of a third layer previously deposited by non-rotation on a third substrate while holding the third substrate stationary without rotation inside the reaction chamber, obtaining a predicted layer growth rate distribution on the third substrate predicted as if obtained had the layer been deposited by rotation based on the third layer thickness data, and offsetting the predicted layer growth rate.

According to another and further aspect of the present invention, a method for depositing a layer on a substrate comprises a gas flow step of rotating a substrate and flowing a reactant gas over a surface of the rotating substrate, and a gas flow rate adjustment step of adjusting the gas flow rates of a plurality of gas flow paths for controlling a gas flow velocity distribution laterally across the reactant gas flow. The gas flow rate adjustment step comprises obtaining layer thickness data indicating a thickness of a layer previously deposited by rotation on a substrate while rotating the substrate inside the reaction chamber, obtaining a deviation between layer growth rates at various locations on the first substrate and a predetermined target layer growth rate based on the layer thickness data, and using predetermined layer growth sensitivity data that defines a sensitivity to a change in layer growth rate distribution on the substrate caused by a change in the respective gas flow rates of the plurality of gas flow paths to reduce the deviation between the layer growth rates at the various locations on the substrate and the target layer growth rate.

### BRIEF DESCRIPTION OF THE DRAWINGS

FIG. 1 is a sectional view of the main components of a layer depositing reactor according to one embodiment of the present invention;

FIG. 2 is a plan view of a lower liner 24 and a susceptor 26, together with a variety of components for gas flow supply mounted on the lower liner 24, of the layer depositing reactor along a line A-A shown in FIG. 1;

FIG. 3A is a plan view of one of two inserters 36 and FIG. 3B is a front view of the one inserter 36 as seen from an upstream side of a gas flow;

FIG. 4A is a plan view of a baffle 38 and FIG. 4B is a front view of the baffle 38 as seen from the upstream side of the gas flow;

FIG. 5A is a plan view of a blade unit 40 and FIG. 5B is a front view of the blade unit 40 as seen from the upstream side of the gas flow;

FIG. 6 is a perspective view of a gas flow deflector plate 41 inserted in a gas transport channel 40CC in the center of the blade unit 40;

FIG. 7 is a plan view illustrating operation of the gas flow deflector plate 41;

FIG. 8 is a piping diagram showing the configuration of a gas piping system for supplying a reactant gas to a reaction device 20;

FIG. 9 is a piping diagram showing a variation of such gas piping system;

FIG. 10 shows gas flow velocity distribution of one gas flow path for illustrating the operation of the baffle 38;

FIG. 11 is a flow chart illustrating overall adjustment control of gas flow rate by a control device 66;

FIG. 12 is a flow chart illustrating in greater detail a process of adjustment of flow rate setting distribution from step S2 to step S3 shown in FIG. 11;

FIGS. 13A, 13B and 13C illustrate in detail the flow rate setting distribution adjustment process of step S3 shown in FIG. 11;

FIGS. 14A and 14B illustrate in detail the flow rate setting distribution adjustment process of step S3 shown in FIG. 11;

FIG. 15 is a flow chart illustrating in greater detail a multiple flow rate fine adjustment process performed in step S9 shown in FIG. 11;

FIG. 16 illustrates a layer growth rate deviation ΔGR(x) used in the multiple flow rate fine adjustment process performed in step S9 shown in FIG. 11;

FIG. 17 shows examples of layer growth sensitivity data at each flow rate regulator (each gas flow path) used in the multiple flow rate fine adjustment process performed in step S9 shown in FIG. 11;

FIG. 18 is a flow chart illustrating a variation of gas flow rate adjustment control;

FIG. 19 is a plan view of layer thickness measurement direction in the gas flow rate adjustment control; and

FIGS. 20A and 20B illustrate in detail the control process shown in FIG. 18.

### DESCRIPTION OF THE PREFERRED EMBODIMENTS

Preferred embodiments of the present invention will now be described in detail with reference to the accompanying drawings.

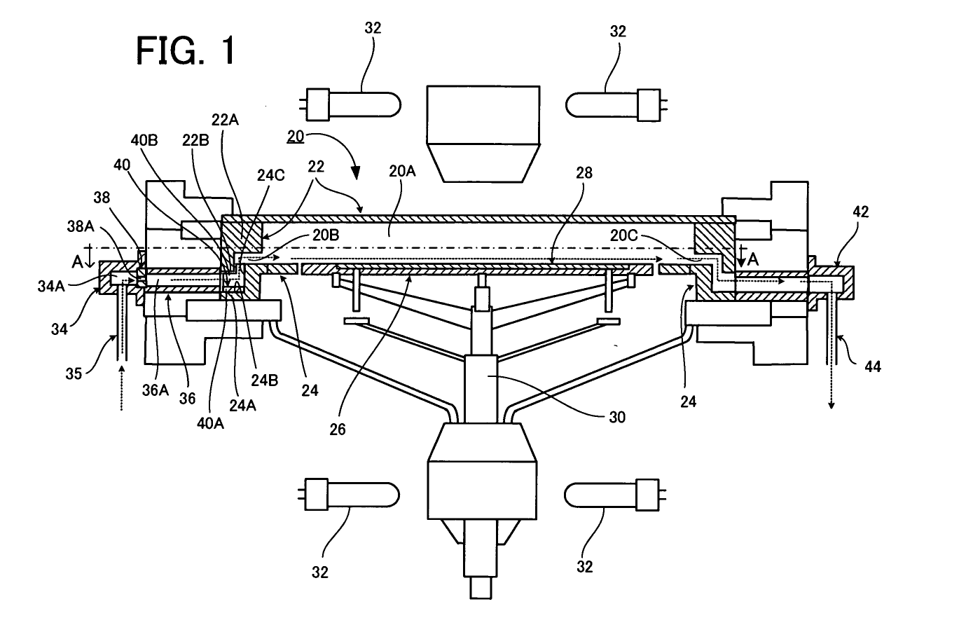

FIG. 1 is a sectional view of the main components of a layer depositing reactor according to one embodiment of the present invention. This layer depositing reactor can be used to form an epitaxial layer of semiconductive material like silicon on the surface of a semiconductor wafer such as a silicon wafer.

As shown in FIG. 1, the layer depositing reactor comprises an internal reaction device 20 having a reaction chamber 20A. The shape of the reaction chamber 20A is that of a substantially flat cylinder. The entire top surface of the reaction chamber 20A is covered by a substantially disc-shaped upper liner 22. In other words, the upper liner 22 forms the ceiling wall of the reaction chamber 20A. The bottom wall of the reaction device 20 is composed of a substantially circular lower liner 24 and a disc-shaped susceptor 26 disposed within a circular opening on the inside of the lower liner 24.

The upper liner 22 has along its entire periphery a downwardly projecting protruding annular part 22A. The protruding annular part 22A of the upper liner 22 is coupled to a periphery 24B of the lower liner 24 to form the side walls of the reaction chamber 20A. A wafer 28 is placed on the susceptor 26. The susceptor 26 is coupled to a rotary drive shaft 30 at its bottom surface and is rotatably driven about the center of the wafer 28 as the axis of rotation during the layer deposition process.

Multiple heating lamps 32, 32, . . . for heating are arrayed in circles both above and below the reaction chamber 20A. To enable radiant heat from the heating lamps 32, 32, . . . to be transmitted optimally to the wafer 28, the main components of the upper liner 22, the lower liner 24, and the susceptor 28 are made of a transparent, heat-resistant material such as quartz.

The basic structure of the layer depositing reactor described above is well known, and therefore a detailed description thereof is omitted from this specification. What follows is a detailed description of a structure for supplying a gas flow to the interior of the reaction chamber 20A of the layer depositing reactor in accordance with the principle of the present invention.

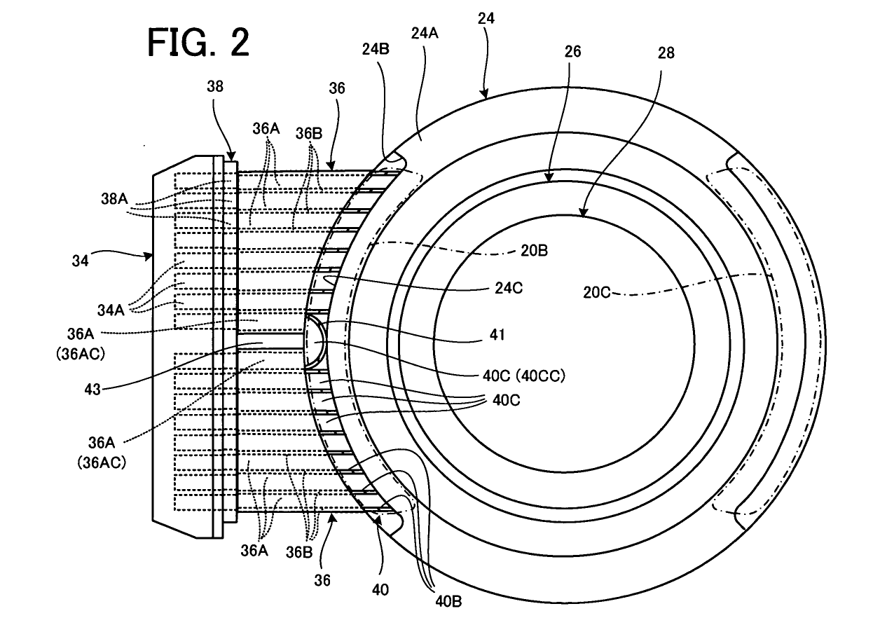

FIG. 2 is a plan view of the lower liner 24 and the susceptor 26, together with a variety of components for gas flow supply mounted on the lower liner 24, as seen along a line A-A shown in FIG. 1. A description is now given of the structure for gas flow supply of the layer depositing reactor, with reference to FIG. 1 and FIG. 2.

A gas inlet port 20B is formed at the edge of one side (the left side in the drawings) of the reaction chamber 20A. A gas exhaust port 20C is formed at the edge of a side opposite the gas inlet port 20B of the reaction chamber 20A. As shown in FIG. 2, both the gas inlet port 20B and the gas exhaust port 20C are located at positions near the outside of the periphery of the wafer 28, extending in an arc substantially parallel to the periphery of the wafer 28. The direction in which the gas inlet port 20B and the gas exhaust port 20C extend along the periphery of the wafer 28 (the vertical direction in FIG. 2) is hereinafter referred to as the “widthwise direction”. The dimensions of the widthwise direction of the gas inlet port 20B and the gas exhaust port 20C, that is, the widths, are slightly larger than the diameter of the wafer 28 on the susceptor 26. The centers of the widthwise directions of the gas inlet port 20B and the gas exhaust port 20C, respectively, match the center of the wafer 28 in the same widthwise direction. Therefore, in the interior of the reaction chamber 20A, the reactant gas flows from the gas inlet port 20B to the gas exhaust port 20C in the form of a belt having a width wide enough to cover the entire surface area of the wafer 28. This belt-shaped reactant gas flow passes over the entire surface area of the wafer 28 and forms an epitaxial layer on the surface of the wafer 28. The flow velocity distribution in the widthwise direction of this reactant gas flow determines the layer thickness distribution of the epitaxial layer on the surface of the wafer 28.

A more detailed description is now given of the structure of the gas inlet port 20B described above. Specifically, a step-shaped concave portion 24B is formed on a peripheral portion 24A of the lower liner 24. This step-shaped concave portion 24B is downwardly concave to a greater extent than the other portions of the lower liner 24 as seen in cross-section along the direction of gas flow shown in FIG. 1 (hereinafter this cross-section is referred to as the “vertical cross-section”), and extends in an arc over a wider distance range than the diameter of the wafer in the widthwise direction as shown in FIG. 2. Moreover, a stepped-shaped convex portion 22B is formed on the protruding annular part 22A of the upper liner 22 opposite the above-described step-shaped concave portion 24B. This step-shaped convex portion 22B protrudes downward toward the step-shaped concave portion 24B as seen in the vertical sectional view shown in FIG. 1, and moreover, in the widthwise direction extends in an arc over the same distance range as that of the step-shaped concave portion 24B. The gas inlet port 20B described above is formed between a portion where the step-shaped concave portion 24B of the peripheral portion 24A of the lower liner 24 exists and a portion where the step-shaped convex portion 22B of the protruding annular part 22A of the upper liner 22 exists. The gas inlet port 20B is bent in the shape of a staircase when seen in the vertical sectional view shown in FIG. 1, through which the reactant gas flows in the direction of the dotted line arrows shown in FIG. 1. As a result, the reactant gas flow hits a front wall 24C of the step-shaped concave portion 24B inside the gas inlet port 20B and rises upward to enter the interior of the reaction chamber 20A.

The structure of the gas exhaust port 20C is substantially the same as that of the gas inlet port 20B described above.

An inlet flange 34 for introducing the reactant gas into the interior of the reaction chamber 20A is mounted on an outside surface of the side on which the gas inlet port 20B of the reaction device 20 is located and opposite thereto. Inside the inlet flange 34 are a plurality (for example 16) of gas chambers 34A. A plurality (for example 16) of gas supply pipes 35 are connected to the inlet flange 34, with the gas supply pipes 35 communicating with the gas chambers 34A.

Between the inlet flange 34 and the gas inlet port 20B are inserted two symmetrically shaped, plane-shaped inserters 36 as shown in FIG. 2. The boundary between the two inserters 36 is located at the center in the widthwise direction of the gas inlet port 20B. Inside the inserters 36 is a plurality of gas flow paths 36A (for example eight), making, for example, a total of 16 gas flow paths 36A inside the two inserters 36. The combined width of the two inserters 36 is substantially the same as the width of the gas inlet port 20B. A laterally long, thin, column-shaped baffle 38 is inserted between the two inserters and the inlet flange 34. Inside the baffle 38 is a plurality of flow rectifying holes 38A (for example 16). The gas chambers 34A inside the inlet flange 34 communicate with the flow rectifying holes 38A inside the baffle 38, the flow rectifying holes 38A inside the baffle 38 communicate with the gas flow paths 36A inside the two inserters 36, and the plurality of gas flow paths 36A inside the two inserters 36 all communicate with the gas inlet port 20B.

A long, thin, block-shaped outlet flange 42 for expelling the reactant gas to the exterior of the reaction chamber 20A is mounted on an outside surface of the side on which the gas exhaust port 20C of the reaction chamber 20A is located and opposite thereto. One or a plurality of gas exhaust pipes 44 are connected to the outlet flange 42.

As indicated by the dotted line arrows in FIG. 1, the reactant gas enters the gas chambers 34A inside the inlet flange 34 from the gas supply pipes 35, enters the gas inlet port 20B through the flow rectifying holes 38A inside the baffle 38 and the gas flow paths 36A inside the two inserters 36, passes through the gas inlet port 20B, forms a belt-shaped gas flow, and flows into the interior of the reaction chamber 20A. The belt-shaped gas flow flowing into the interior of the reaction chamber 20A from the gas inlet port 20B passes over the entire surface area of the wafer 28 on the susceptor 26 and forms an epitaxial layer on the surface of the wafer 28. Thereafter, the reactant gas flow enters the gas exhaust port 20C, passes through the interior of the outlet flange 42 and exits through the gas exhaust pipe 44. The layer thickness distribution of the epitaxial layer on the surface of the wafer 28 is determined by the gas flow velocity distribution in the widthwise direction of the reactant gas flow inside the reaction chamber 20A. The gas flow velocity distribution inside the reaction chamber 20A is determined by the gas flow velocity distribution of the plurality of gas flow paths 36A inside the two inserters 36.

A more detailed description is now given particularly of the structure of the inserters 36, the baffle 8, the inlet flange 34, and the gas inlet port 20B.

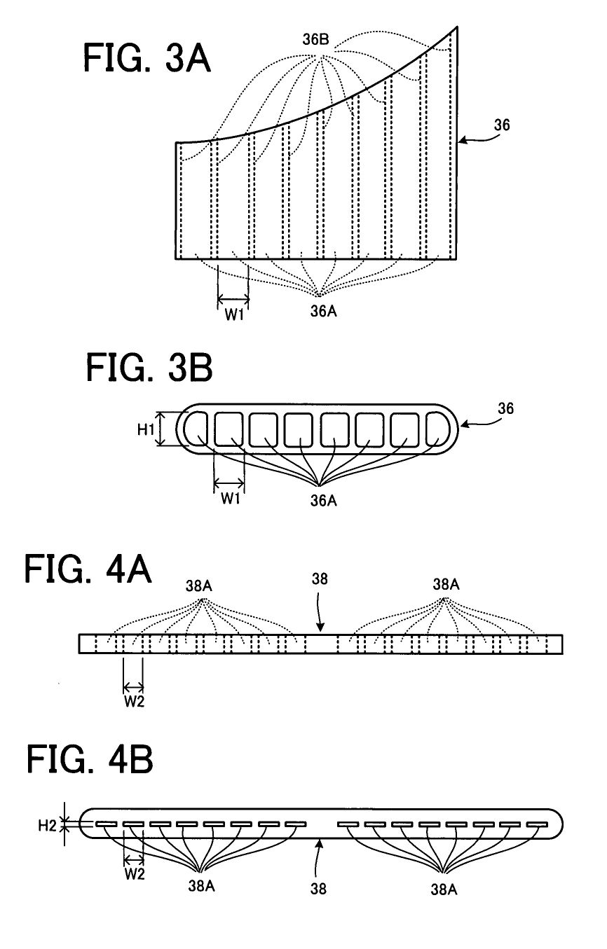

FIG. 3A shows a plan view of one of the two inserters 36, and FIG. 3B shows a front view of one inserter 36 as seen from the upstream side of the gas flow (that is, from the baffle 38 side). It should be noted that a rear view of the same inserter 36 from a downstream side of the gas flow (from the gas inlet port 20B side) is the same as the front view shown in FIG. 3B. In addition, the structure of the other inserter 36 is the same as the structure shown in FIGS. 3A and 3B (except that left and right in the plan view shown in FIG. 3A are reversed).

As shown in FIG. 1, FIG. 2, and FIGS. 3A and 3B, inside the inserters 36, the plurality of gas flow paths 36A that communicate from the baffle 38 side to the gas inlet port 20B side is arrayed in a single line in the widthwise direction. Adjacent gas flow paths 36A are separated from each other by side walls 36B. As shown in FIG. 3B, the shape of the gas flow paths 36A in cross-section as cut across the flow of gas at a right angle thereto (hereinafter, this cross-section in a direction that is at a right angle to the flow of gas is referred to as the “lateral cross-section”) is for example rectangular, ovoid, or a shape closely approximate thereto. In the present embodiment, the number of gas flow paths 36A inside each inserter 36 is for example eight, for a total of 16 gas flow paths 36A for the two inserters 36.

As is described later, the gas flow velocities of the flows in each of the 16 gas flow paths 36A inside the two inserters 36 is controlled independently. Alternatively, as a variation, two of the gas flow paths 36A of the 16 gas flow paths 36A inside the two inserters 36 located at symmetrical positions with respect to the center of the widthwise direction are paired to form a single pair, the 16 gas flow paths 36A are divided into eight pairs, and the gas flow velocities of the flows in each of the eight pairs gas are controlled independently.

FIG. 4A shows a plan view of the baffle 38 and FIG. 4B shows a front view of the baffle 38 as seen from the upstream side of the gas flow (the inlet flange 34 side). It should be noted that a rear view of the baffle 38 as seen from the downstream side (the inserter 36 side) is the same as the front view shown in FIG. 4B.

As shown in FIG. 1, FIG. 2 and FIGS. 4A and 4B, inside the baffle 38 a plurality of flow rectifying holes 38A (for example 16) communicating from the inlet flange 34 side to the inserter 36 side is arrayed in a single line in the widthwise direction. The plurality of flow rectifying holes 38A communicates with the respective plurality of gas flow paths 36A in the inserters 36. Different flow rectifying holes 38A are separated from each other. As shown in FIG. 4B, the shape of the flow rectifying holes 38A is horizontal cross-section is that of a long, narrow slit in the widthwise direction. A width W2 of the flow rectifying holes 38A in horizontal cross-section is substantially the same as a width W1 of the corresponding gas flow paths 36A (see FIGS. 3A, 3B). In other words, the flow rectifying holes 38A extend across the entire width of the corresponding gas flow paths 36A. In addition, a height H2 of the flow rectifying holes 38A in horizontal cross-section is the same across the entire width thereof, and further, is much smaller than a height H1 of the corresponding gas flow paths 36A (see FIG. 3B). As is described later, the flow rectifying holes 38A fulfill the function of flattening the distribution of the gas flow velocity inside the gas flow paths 36A.

As shown in FIG. 1 and FIG. 2, a plurality of separate gas chambers 34A (for example 16) is formed inside the inlet flange 34. Each of these multiple gas chambers 34A inside the inlet flange 34 communicates with one of the plurality of flow rectifying holes 38A inside the baffle 38. A plurality of gas supply pipes 35 (for example 16) is connected to the plurality of gas chambers 34A in the inlet flange 34. As is described later, the respective gas flow rates of each of the plurality of gas supply pipes 35 are independent of each other and can be adjusted individually.

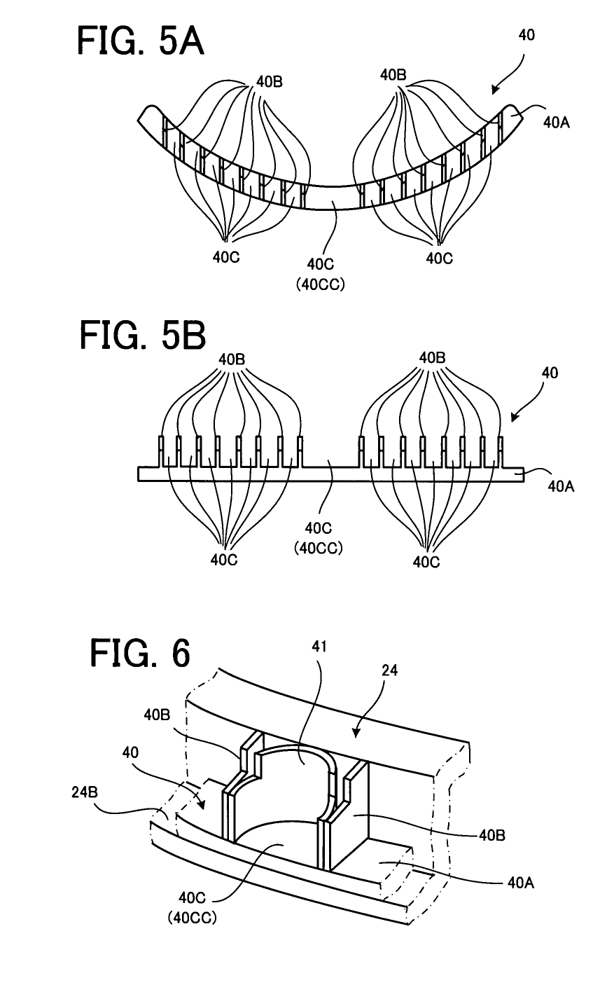

As shown in FIG. 1 and FIG. 2, a blade unit 40 is inserted into the step-shaped concave portion 24B that occupies approximately half the area upstream of the gas inlet port 20B. FIG. 5A is a plan view of the blade unit 40 and FIG. 5B is a front view of the blade unit 40 as seen from the upstream side of the gas flow (the inserter 36 side).

As shown in FIG. 1, FIG. 2, and FIGS. 5A and 5B, the blade unit 40 comprises a flat, planar base plate 40A in the same arc shape as that of the step-shaped concave portion 24B and a plurality of blades 40B (for example 16) projecting perpendicularly from the top of the base plate 40A. The blade unit 40 is an independent and separate component not integrated into a single unit with the lower liner 24 (in other words, is detachable from the lower liner 24), and is placed atop the step-shaped concave portion 24B of the lower liner 24. Each of the multiple blades 40B of the blade unit 40 are aligned with one of the side walls 36B of the gas flow paths 36A inside the inserters 36. Accordingly, a plurality of separate and individual gas transport channels 40C (for example 15) is formed on the step-shaped concave portion 24B by the plurality of blades 40B. Each of these multiple gas transport channels 40C communicates with one of the multiple gas flow paths 36A inside the two inserters 36. However, as shown in FIG. 2, only a comparatively wide single gas transport channel 40CC located at the center of the step-shaped concave portion 24B in the widthwise direction thereof communicates with two gas flow paths 36AC located at the center of the two inserters in the widthwise direction thereof. A gas flow deflector plate 41 in the shape of a flat plane bent into a semicircular arc shape is inserted in the central gas transport channels 40CC.

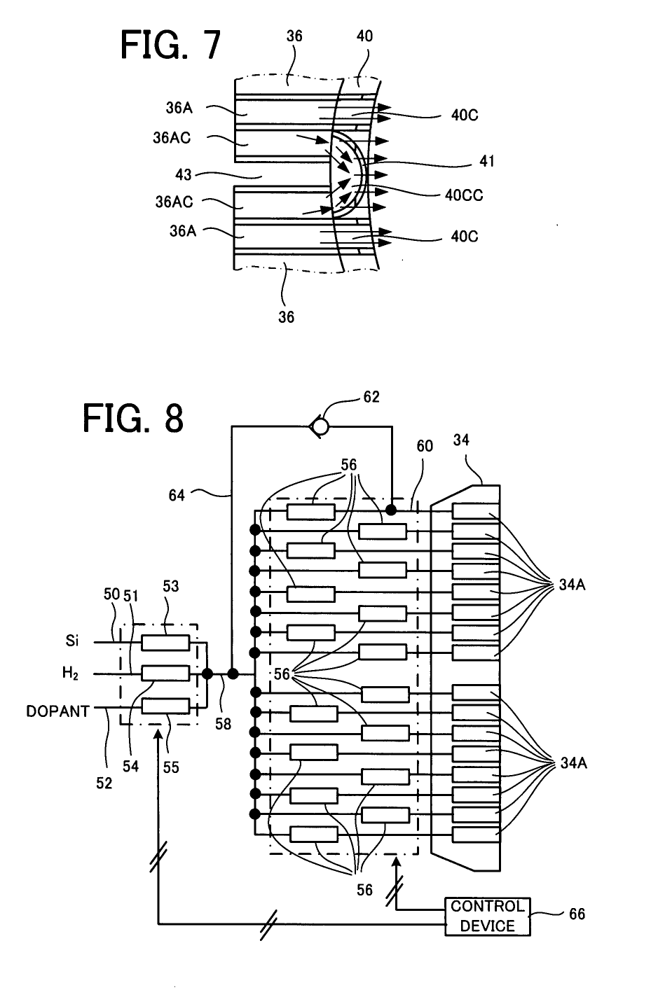

FIG. 6 is a perspective view of the gas flow deflector plate 41 and FIG. 7 is a plan view illustrating operation of the gas flow deflector plate 41.

As shown in FIG. 2 and FIG. 6, a concave surface of the gas flow deflector plate 41 faces the two central gas flow paths 36AC. A support wall 43 for fixing the two inserters 36 in place is located between the two central gas flow paths 36AC, with the support wall 43 having a thickness greater than that of the side walls 36B of the gas flow paths 36A inside the inserters 36. As a result, if gas flows from each of the two central gas flow paths 36AC are simply directed as is into the gas transport channels 40CC and to the reaction chamber 20A, the gas flow velocity distribution in the widthwise direction inside the reaction chamber 20A is such that the gas flow velocity becomes particularly low at a central point corresponding to the location of the support wall 43, and as a result, the thickness of the epitaxial layer deposited on the wafer 28 becomes particularly thin near the center of the wafer 28. By contrast, with the gas flow deflector plate 41 present in the central gas transport channel 40CC, as shown in FIG. 7, the concave surface of the gas flow deflector plate 41 bends the gas flows from the two central gas flow paths 36AC toward the center, thereby remedying the above-described problem of the gas flow velocity distribution in the widthwise direction becoming particularly low.

FIG. 8 is a piping diagram showing the configuration of a gas piping system provided on the outside of the reaction device 20 described above for supplying the reactant gas to the reaction device 20.

The reactant gas is a compound gas consisting of multiple component gases, such as silicon gas, hydrogen gas and a predetermined dopant gas. As a result, as shown in FIG. 8, there is a plurality of gas sources, such as a silicon gas source, a hydrogen gas source, and a dopant gas source, with a plurality of component gas supply pipes 50, 51, 52 coming from the respective plurality of component gas sources converging at a single reactant gas supply source pipe 58. Gas flow regulators 53, 54, 55 are provided on each of the component gas supply pipes 50, 51, 52. The gas flow regulators 53, 54, 55 are controlled by a control device 66 using a computer, enabling the overall flow rate of the reactant gas supplied to the reaction device 20 and the relative proportions of the component gases in the reactant gas to be adjusted.

The reactant gas supply source pipe 58 branches into a plurality of (for example 16) reactant gas supply branch pipes 60. Each of the plurality of reactant gas supply branch pipes 60 is connected to one of a plurality of (for example, 16) gas chambers 34A1-34A16 inside the inlet flange 34. A gas flow regulator 56 capable of adjusting the gas flow rate essentially steplessly (that is, continuously) is provide on each one of the plurality of reactant gas supply branch pipes 60. These 16 gas flow regulators 56 are controlled by the control device 66, enabling the gas flow rate flowing to each of the 16 gas chambers 34A (and in turn through each of the 16 gas flow paths 36A shown in FIG. 2) to be adjusted to any value separately and independently of all the others.

Further, in the event that the gas pressure in the reactant gas supply source pipe 58 becomes abnormally high due to a malfunction in one of the gas flow regulators 56 or for some other reason, a safety relief pipe 64 having a safety relief valve 62 for releasing excess gas to the outside of the reaction chamber 20A and lowering the pressure is connected between the reactant gas supply source pipe 58 and a single reactant gas supply branch pipe 60 that is connected to the single outermost gas flow path 36A of the 16 gas flow paths 36A.

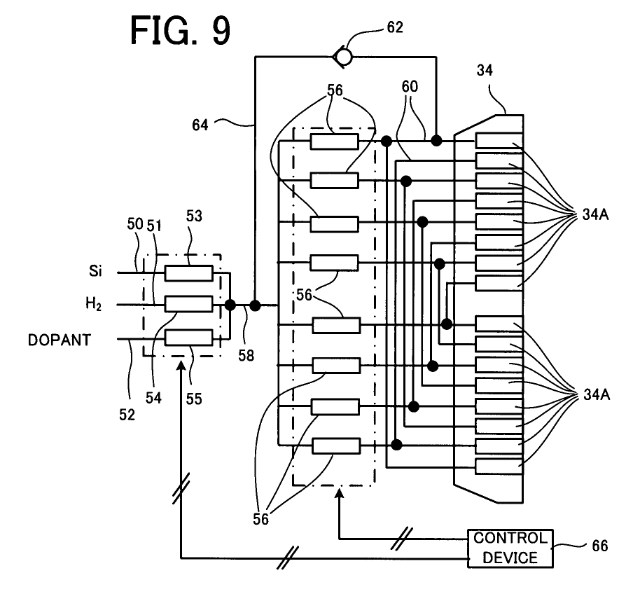

In the gas piping system shown in FIG. 8 described above, a dedicated gas flow regulator 56 is provided for each and every one of the gas flow paths 36A, such that the gas flow rates of all the gas flow paths 36A can be adjusted independently. Alternatively, in place of this arrangement, a gas piping system like that shown in FIG. 9 may be employed. In the gas piping system shown in FIG. 9, the 16 gas supply branch pipes 60 are divided into eight pairs and one gas flow regulator 56 is provided for each pair. The two gas supply branch pipes 60 that comprise a single pair are connected to the two gas flow paths 36A that, of the 16 gas flow paths 36A shown in FIG. 2, are disposed symmetrically about the center in the widthwise direction. Therefore, with the gas piping system like that shown in FIG. 9, no matter how the gas flow rates of the pairs is adjusted, the gas flow velocity distribution in the widthwise direction of the gas flow entering the reaction chamber 20A from the gas inlet port 20B is substantially symmetrical about the center in the widthwise direction.

A description is now given of the operation of the layer depositing reactor having the configuration described above.

The flow velocity distribution in the widthwise direction of the reactant gas flow into the reaction chamber 20A from the gas inlet port 20B is controlled by each of the gas flow velocities of the 16 gas flow paths 36A arrayed across the entire gas inlet port 20B in the widthwise direction thereof (in other words, eight in the range of one side, divided in two at the center in the widthwise direction). It should be noted that the number 16 as the number of gas flow paths 36A is but one example thereof, insofar as the optimum number changes depending on the size of the wafer 28.

With respect to the number of gas flow paths 36A, according to research conducted by the inventors of the present invention, it is preferable that conditions like the following be satisfied. Specifically, increasing the number of gas flow paths 36A has the advantage of enabling the gas flow velocity distribution to be controlled more finely. At the same time, however, a problem arises in that increasing the number of gas flow paths 36A also reduces the pitch between adjacent gas flow paths 36A (that is, the distance between the centers of the gas flow paths 36A), which magnifies the effects of diminished gas flow velocities due to the side walls 36B of the gas flow paths 36A. When focusing on the former advantage, the desirable number of gas flow paths 36A is five or more over the range of one side where the gas inlet port 20B is divided into two at the center in the widthwise direction, in other words, ten or more across the entire gas inlet port 20B in the widthwise direction (where there are two central gas flow paths 36A as in the structure shown in FIG. 2), or nine or more (where the central gas flow paths 36A are consolidated into a single path), and preferably more. On the other hand, focusing on the latter disadvantage, and further, taking into consideration the fact that the side walls 36B of the gas flow paths 36A must be at least approximately 1-2 mm, the desirable pitch between adjacent gas flow paths 36A is at least 10 mm and preferably more. Alternatively, in place of this pitch-related requirement, the following gas flow velocity-related condition may be taken into consideration. Specifically, it is desirable that a difference between a maximum gas flow velocity (typically the gas flow velocity at a position corresponding to the center of the gas flow paths 36A) and a minimum gas flow velocity (typically the gas flow velocity at a position corresponding to the location of the side walls 36B) in the range of a single pitch between gas flow paths 36A in the widthwise direction of the gas flow immediately after exiting the gas inlet port 20B be 0.5 m/sec or less.

Assuming a wafer 28 diameter of 200 mm, the total size in the widthwise direction of the gas inlet port 20B is 200 mm or more, for example, from approximately 210 mm to approximately 290 mm. In this case, if the total number of gas flow paths 36A is 16 (eight on each side) as shown in FIG. 2, the pitch between gas flow paths 36A becomes from approximately 12 mm to approximately 18 mm, thus satisfying both the requirement for the number of gas flow paths 36A and the pitch requirement. Assuming a wafer 28 diameter of 300 mm, the total number of gas flow paths 36A may for example be 24 (12 on each side), with the pitch between gas flow paths 36A becoming once again from approximately 12 mm to approximately 18 mm, thus satisfying both conditions described above.

As can be seen from the foregoing examples, the range of from approximately 12 mm to approximately 18 mm for the pitch between gas flow paths 36A can be called one preferable condition satisfying both requirements described above. In addition, in terms of the number of gas flow paths 36A, if the diameter of the wafer 28 is 200 mm, then the number of gas flow paths 36A on a side ranges from seven to ten, of which the eight gas flow paths 36A on a side employed in the embodiment are particularly preferable. If the diameter of the wafer is 300 mm, then the number of gas flow paths 36A on a side ranges from ten to 15, with the 12 on a side described above being particularly preferable.

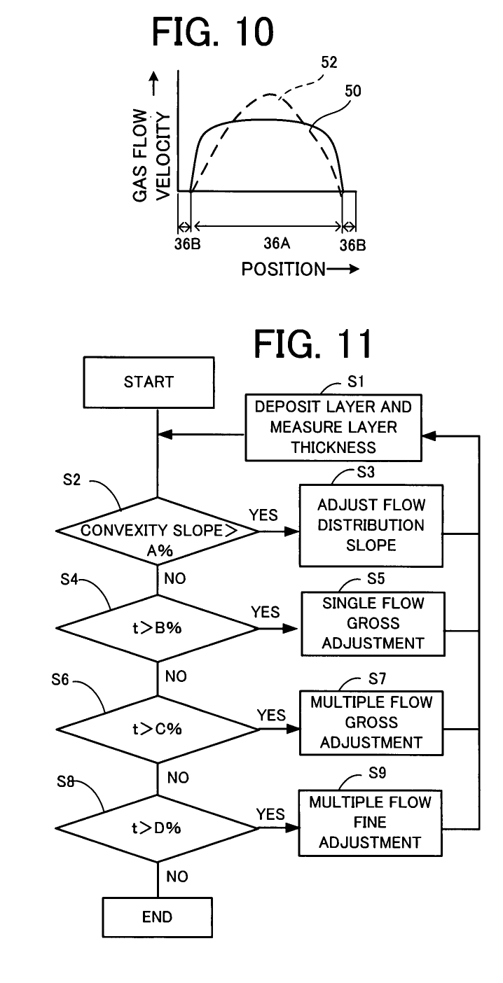

In addition to the preferred settings for gas flow paths 36A pitch and numbers such as is described above, the flow rectifying holes 38A in the baffle 38 located upstream of the gas flow paths 36A have the effect of equalizing the flow rate distribution within the gas flow paths 36A, by which the requirement relating to flow velocity described above is even more easily and better satisfied. Specifically, the flow rectifying holes 38A are long, narrow slit-shaped holes extending in the widthwise direction across the entire width of the gas flow paths 36A, having a height H2 that is constant across the entire width of the gas flow paths 36A. As the gas flow passes through such narrow flow rectifying holes 38A, the gas flow velocity distribution in the widthwise direction of the gas flow immediately after exiting the flow rectifying holes 38A is constant over the entire width of the gas flow paths 36A, and further, that gas flow velocity distribution determines the gas flow velocity distribution of the gas flow when the gas flow later flows through the gas flow paths 36A. As a result, the flow velocity distribution in the widthwise direction when the gas flow exits the gas flow paths 36A becomes as indicated by a solid line 50 in the graph shown FIG. 10. For purposes of comparison, the flow velocity distribution in the widthwise direction of the gas flow when it exits the gas flow paths 36A when there is no baffle 38 is indicated by a dashed line 52 in FIG. 10. As can be seen by a comparison of the two lines 50, 52, when there is a baffle 38 present the effect of the decrease in flow velocity due to the side walls 36B on both sides on the flow velocity distribution in the widthwise direction of the gas flow when the gas flow exits the gas flow paths 36A is smaller, and the gas flow velocity distribution is more uniform, than when there is a no baffle 38.

Further, as described with reference to FIG. 1 and FIG. 2, the gas flow velocity distribution formed by the plurality of gas flow paths 36A inside the inserters 36 is well maintained inside the step-shaped concave portion 24B by the plurality of gas transport channels 40C formed by the blade unit 40 placed atop the step-shaped concave portion 24B in the front half of the gas inlet port 20B. Then, when the gas flow passes the step-shaped concave portion 24B, the gas flow strikes the front wall 24C of the step-shaped concave portion 24B and rises upward before flowing into the interior of the reaction chamber 20A, and further, the gas inlet port 20B portion downstream from the front wall 24C is continuous in the widthwise direction without being divided. As a result, fluctuations in the gas flow velocity distribution due to the blade unit 40B are diminished by the rear half of the gas inlet port 20B which is not divided, thus improving the smoothness of flow velocity distribution in the widthwise direction of the gas flow entering the reaction chamber 20A from the gas inlet port 20B.

As a result of the combined effects of the parts described above, it becomes possible to adjust the gas flow velocity distribution in the widthwise direction of the gas flow inside the reaction chamber 20A to a desired distribution. By using the layer depositing reactor of the embodiment described above and adjusting the gas flow rate using a method that is described later, according to a test of silicon epitaxial layer deposited on a silicon wafer having a diameter of 200 mm, a high-quality epitaxial layer can be obtained of extremely high uniformity in which a difference between a maximum layer thickness of the epitaxial layer and a minimum layer thickness of the epitaxial layer (hereinafter referred to as “layer thickness fluctuation”) is 1% (+0.5%) or less of the average layer thickness of the epitaxial layer.

In addition, in the above-described embodiment, the blade unit 40 inside the step-shaped concave portion 24B of the gas inlet port 20B is a separate component from the lower liner 24 and does not form a single unit with the lower liner 24. Consequently, heat from the high-temperature lower liner 24 is not transmitted easily to the blade unit 40, and accordingly, the blade unit 40 does not become as hot as the lower liner 24. As a result, the amount of silicon crystals growing on and attaching to the surface of the blade unit 40 declines. Further, during maintenance, the blade unit 40 can be removed easily from the lower liner 24, thus facilitating removal of any attached silicon crystals.

Moreover, as shown in FIG. 8 and FIG. 9, the safety relief pipe 64 is connected to the reactant gas supply branch pipe 60 that is connected to the outermost gas flow path 36A, thereby minimizing any adverse effect on layer deposition when the safety relief pipe 64 is activated because, of all the gas flow paths 36A, the outermost gas flow path 36A has the smallest effect on layer deposition.

Next, a detailed description is given of gas flow rate adjustment control performed by the control device 66 shown in FIG. 8 and FIG. 9.

FIG. 11 is a flow chart illustrating overall adjustment control of gas flow rate by the control device 66.

The purpose of this control is to adjust the gas flow velocity distribution in the widthwise direction of the gas inlet port 20B in the reaction chamber 20A so as to make the layer thickness distribution of the epitaxial layer on the surface of the wafer 28 as uniform as possible. In this control process, the control device 66 operates the plurality of gas flow regulators 56 connected to the plurality of gas supply branch pipes 60 shown in FIG. 8 and FIG. 9 and adjusts the gas flow rates (the volume of gas flowing per unit of time) flowing through each of the plurality of gas flow paths 36A, that is, the gas flow rate distribution in the widthwise direction in the gas inlet port 20B.

In FIG. 11, first, in step S1, an experimental layer is deposited on the wafer 28. As with the deposition of a layer on the wafer 28 to create a product, this experimental layer deposition is also carried out with the wafer 28 rotating. After experimental layer deposition, the thickness of the deposited layer is measured at multiple different places on the surface of the wafer 28. In the first experimental layer deposition conducted, the control device 66 adjusts the above-described gas flow rate distribution (that is, the gas flow rates of the plurality of gas flow regulators 56) to a preset initial flow rate setting. Any appropriate flow rate value assumed to be appropriate based on experience, for example, may be employed as the initial flow rate setting.

In the steps following step S2, the layer thickness distribution is checked for unevenness based on the layer thickness data obtained by measurement in step S1, and the flow rate setting at the control device 66 is adjusted to correct any such unevenness and make the layer thickness distribution uniform. The flow rate setting adjustment process can be divided into a plurality of stages representing different degrees of fineness of control or different purposes. In FIG. 11, the flow rate setting adjustment process is divided into four stages. The first stage is flow rate distribution slope adjustment of step S3, the second stage is single flow rate gross adjustment of step S5, the third stage is multiple flow rate gross adjustment of step S7, and the fourth stage is multiple flow rate fine adjustment of step S9. Depending on the extent of the unevenness of the layer thickness distribution obtained from the test layer deposition of step S1, the checks of steps S2, S4, S6 and S8 are carried out, and from those results the next flow rate adjustment stage to be executed is selected from among the foregoing four stages. Whenever any of the stages is executed, the control process returns to step S1 and experimental layer deposition is again carried out using the flow rate setting as adjusted in the executed stage. Once flow rate setting adjustment and experimental layer deposition as described above are repeated several times and the layer thickness distribution of the results of the experimental layer deposition finally becomes so uniform that none of the four stages described above is necessary (NO in step S8), the adjustment control shown in FIG. 11 is finished and the flow rate setting is confirmed. Thereafter, the work of depositing a layer on the wafer 28 is started using the confirmed flow rate setting. It should be noted that the four stages of the flow rate setting adjustment shown in FIG. 11 are but one example, and consequently, more or fewer stages may be employed.

A more detailed description is now given of the routine from step S2 to step S9 shown in FIG. 11.

In step S2, based on the layer thickness distribution obtained by measurement in step S1, a convexity slope of the layer thickness distribution is calculated. The term “convexity slope of the layer thickness distribution” here means the overall slope of the layer thickness distribution in a direction from the center of the wafer 28 to the periphery of the wafer 28, or, to put it another way, the extent of a tendency of the layer thickness to get thinner or thicker the farther the distance away from the center of the wafer 28. In step S2, this convexity slope of the layer thickness distribution is calculated and a check is made to determine whether or not this convexity slope exceeds a predetermined slope threshold value A(%). If the results of the check made in step S2 indicate that the convexity slope does exceed the predetermined threshold slope value A(%) (that is, YES in step S2), then the control process proceeds to step S3 and the slope of distribution of the flow rate settings for the plurality of gas flow regulators 56 at the control device 66 is adjusted so that the convexity slope is revised to zero.

In step S4, based on the layer thickness distribution obtained by measurement in step S1, the extent (for example, in proportion to the average layer thickness) of layer thickness fluctuation (as described above, the difference between the maximum layer thickness and the minimum layer thickness) is calculated and a check is made to determine whether or not the extent of that layer thickness fluctuation exceeds a predetermined drastic fluctuation threshold value B(%) for determining whether or not the extent of layer thickness fluctuation is drastic. If the results of that check are YES, then the control process proceeds to the single flow rate gross adjustment of step S5. In step S5, a single gas flow regulator 56 deemed to have the greatest impact in terms of reducing unevenness in layer thickness distribution is selected according to the locations (such as distance from the center of the wafer 28) of maximum layer thickness, minimum layer thickness, local maximum layer thickness and local minimum layer thickness of the layer thickness distribution, and the flow rate setting of that flow rate regulator 56 is adjusted so as to reduce the unevenness in layer thickness distribution. As a selection method for determining which gas flow regulator 56 to select, a method may be employed in which data defining a correspondence between the locations of maximum layer thickness, minimum layer thickness, local maximum layer thickness and local minimum layer thickness, on the one hand, and a single flow rate regulator 56 to be selected on the other may be set in the control device 66 and that data referenced. In addition, as a method for adjusting the flow rate setting of the selected flow rate regulator 56, a method may be employed in which data defining a correspondence between the relative sizes (for example, difference or ratio) of maximum layer thickness, minimum layer thickness, local maximum layer thickness and local minimum layer thickness with respect to the average layer thickness, on the one hand, and the relative sizes of a flow rate setting after adjustment and a current flow rate setting on the other may be set in the control device 66 and that data referenced.

In step S6, a check is made to determine whether or not the extent of the layer thickness fluctuation described above exceeds a predetermined moderate fluctuation threshold value C(%) (where C<B) for determining whether or not the extent of layer thickness fluctuation is moderate (that is, less than or equal to B but greater than C). If the results of that check are YES, then the control process proceeds to the multiple flow rate gross adjustment of step S7. In step S7, a predetermined plurality of gas flow regulators 56 deemed to have the greatest impact in terms of reducing unevenness in layer thickness distribution is selected according to the positions of maximum layer thickness, minimum layer thickness, local maximum layer thickness and local minimum layer thickness, and the flow rate settings of those flow rate regulators 56 are adjusted so as to reduce the unevenness in layer thickness distribution. As a selection method for determining which gas flow regulators 56 to select, a method may be employed in which data defining a correspondence between the locations of maximum layer thickness, minimum layer thickness, local maximum layer thickness and local minimum layer thickness, on the one hand, and the predetermined plurality of flow rate regulators 56 to be selected on the other may be set in the control device 66 and that data referenced. In addition, as an adjustment method for adjusting the flow rate settings of the selected flow rate regulators 56, a method may be employed in which data defining a correspondence between the relative sizes (for example, difference or ratio) of the maximum layer thickness, minimum layer thickness, local maximum layer thickness and local minimum layer thickness with respect to the average layer thickness, on the one hand, and the relative sizes of the flow rate settings after adjustment and the current flow rate settings on the other may be set in the control device 66 and that data referenced.

In step S8, the extent of the layer thickness fluctuation described above is checked to determine whether or not the layer thickness fluctuation exceeds a predetermined slight fluctuation threshold value D(%) (where D<C<B) for determining whether or not the layer thickness fluctuation is slight (that is, less than or equal to C but greater than D). If the results of that check are YES, then the control process proceeds to the multiple flow rate fine adjustment of step S9. In step S9, based on layer growth sensitivity data for all the flow rate regulators 56 set in the control device 66 in advance, the flow rate settings of all the flow rate regulators 56 are adjusted so as to reduce the unevenness in layer thickness distribution. A detailed description of the adjustment process of step S9 is given later.

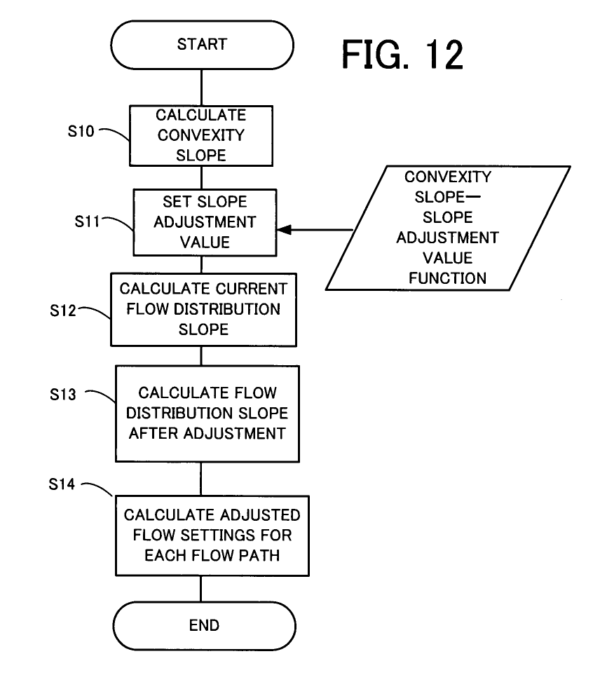

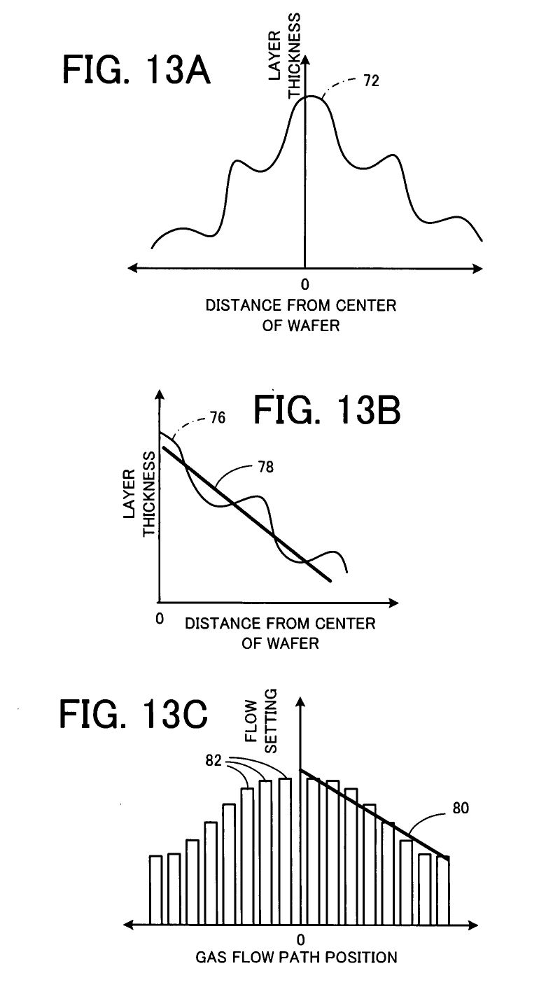

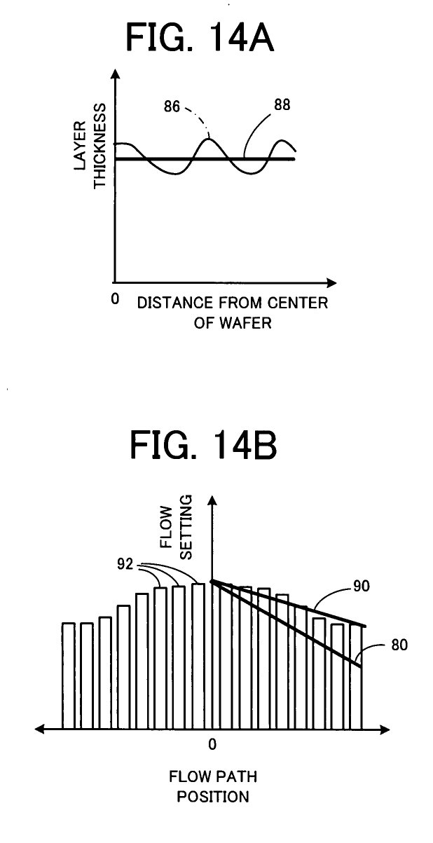

FIG. 12 is a flow chart illustrating in greater detail the process of adjusting a flow rate setting distribution slope from step S2 to step S3. FIGS. 13A to 13C, and FIGS. 14A and 14B, illustrate specific examples of this process.

As shown in FIG. 12, in step S10, the convexity slope of the layer thickness distribution is calculated. For example, where layer thickness data is obtained by measurement of a layer thickness distribution 72 shown in FIG. 13A, the average value of that layer thickness distribution 72 over a range of 360 degrees angle of rotation about the center of the wafer is calculated and a layer thickness distribution 76 as a function of distance from the center of the wafer like that shown in FIG. 13B is obtained. Then, using the least squares method, a convexity slope straight line 78 that most closely approximates the layer thickness distribution 76 is calculated and the slope of that convexity slope straight line 78 is obtained (hereinafter this slope is referred to as the “convexity slope”).

Thereafter, in step S11 shown in FIG. 12, a value for adjusting the slope of the flow rate setting distribution among the gas flow paths 36A from the center of the wafer is calculated (hereinafter referred to as the “slope adjustment value”). In this calculation, convexity slope-slope adjustment value function data 70 set in advance in the control device 66 is referenced. The convexity slope-slope adjustment value function data 70 is data that defines a correspondence between the convexity slope described above and the slope adjustment value described above. By reading out the slope adjustment value for the convexity slope obtained in step S10 from the convexity slope-slope adjustment value function data 70 the slope adjustment value is set.

The slope adjustment value is, for example, like the following: Specifically, as shown in FIG. 13C, current flow rate setting values 82 for the plurality of flow rate regulators 56 assume a certain arrangement or distribution (typically, symmetrical about an origin 0) as a function of the positions of the gas flow paths 36A (where the origin 0 corresponds to the center in the widthwise direction of the gas inlet port 20B). The slope of this distribution of current flow rate setting values 82, as shown in FIG. 13C, can be expressed as the slope of a flow rate distribution straight line 80 that approximates the graph of the setting flow values 82 (hereinafter this slope is referred to as the “flow rate distribution slope”). The above-described slope adjustment value is an adjustment value for changing the current flow rate distribution slope, for example, the relative sizes of the current flow rate slope and the flow rate distribution slope after adjustment (expressed in terms of difference or ratio, for example). The slope adjustment value is set in advance in the convexity slope-slope adjustment value function data 70 so that, when used to adjust the current flow rate distribution 82, a layer thickness distribution 86 whose convexity slope (the slope of a convexity slope straight line 88) is zero as shown in FIG. 14A can be obtained as a result.

After the slope adjustment value is determined in step S11 shown in FIG. 12 as described above, the control process proceeds to step S12 shown in FIG. 12 and the current flow rate distribution slope is calculated. The current flow rate distribution slope is the slope of the current flow rate distribution straight line 80 shown in FIG. 13C. Thereafter, the control process proceeds to step S13 and applies the slope adjustment value determined in step S11 to the current flow rate distribution slope obtained in step S12 to calculate the flow rate distribution slope after adjustment. The flow rate distribution slope after adjustment is the slope of a flow rate distribution straight line 90 after adjustment as shown in FIG. 14B, and is the result of the correction of the slope of the current flow rate distribution straight line 80 by the slope adjustment value.

Thereafter, the control process proceeds to step S14 shown in FIG. 12, in which the flow rate settings of each of the flow rate regulators 56 is adjusted so as to match the flow rate distribution slope after adjustment obtained in step S13. The adjusted flow rate settings are like those indicated by reference numeral 92 shown in FIG. 14B, and have an arrangement or distribution that matches the adjusted flow rate distribution straight line 90.

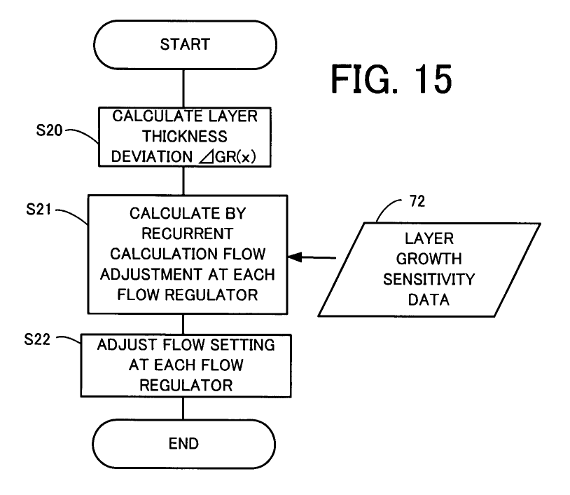

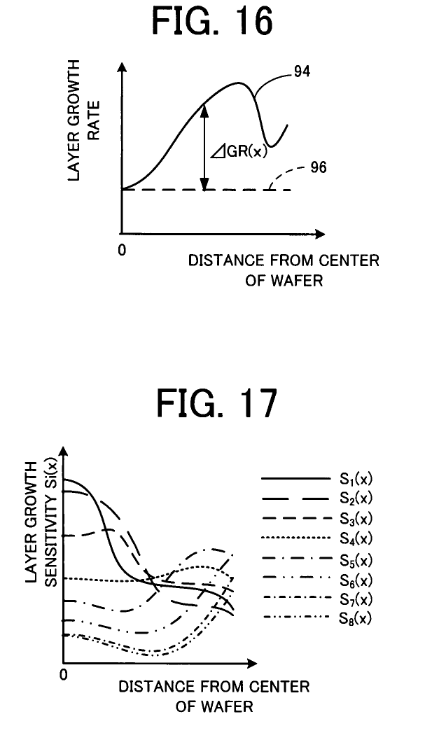

FIG. 15 is a flow chart illustrating in greater detail the multiple flow rate fine adjustment process performed in step S9 shown in FIG. 11. FIG. 16 illustrates a layer growth rate deviation ΔGR(x) used in the multiple flow rate fine adjustment process. FIG. 17 shows examples of layer growth sensitivity data at each gas flow path used in the multiple flow rate fine adjustment process.

In the multiple flow rate fine adjustment process, as shown in FIG. 15, in step S20, based on layer thickness data obtained by measurement in the experimental layer deposition, the layer growth rate deviation ΔGR(x) is calculated as a function of the distance x from the center of the wafer 28. For example, based on the layer thickness data and the time needed for layer growth, a layer growth rate of 94 μm/min as shown in FIG. 16 is calculated as a function of distance x from the center of the wafer. Then, a difference between that layer growth rate 94 and a predetermined target layer growth rate 96 (for example, a minimum rate, a maximum rate or an average rate of the layer growth rate 94, or an arbitrary rate value set in advance) is obtained as the layer growth rate deviation ΔGR(x). The layer growth rate deviation ΔGR(x) is calculated at each of multiple predetermined different distances x set in advance as sampling points.

Thereafter, in step S21 shown in FIG. 15, flow rate adjustment values for each flow rate regulator 56 are calculated based on the layer growth rate deviation ΔGR(x) at the multiple sampling points calculated in step S20. In this calculation, layer growth sensitivity data set in advance in the control device 66 is referenced. The layer growth sensitivity data, as shown in the example shown in FIG. 17, is the aggregate of layer growth sensitivity functions S₁(x) to S_{N}(X) set in advance for each flow rate regulator 56 (put another way, for each gas flow path 36A; more precisely, for each pair of gas flow paths 36A where two gas flow paths 36A symmetrically located are treated as one pair) (where N is the number of pairs of gas flow paths; although N=8 in the example shown in the drawing, such is but one example thereof). For example, the first layer growth sensitivity function S₁(x) corresponds to the most centrally located pair of gas flow paths 36A (the two central gas flow paths 36AC shown in FIG. 2), the second layer growth sensitivity function S₂(x) corresponds to the next most centrally located pair of gas flow paths 36A, with the layer growth sensitivity function Sᵢ(x) corresponding to successively more outwardly located gas flow paths 36A as the suffix number represented by i increases up to the final Nth (in the present example the 8^{th}) layer growth sensitivity function S_{N}(x) (in the present example S₈(x)) corresponding to the outermost pair of gas flow paths 36A.

As shown in FIG. 17, the layer growth sensitivity function Sᵢ(x) expresses a ratio of change in the layer growth rate (μm/min) on the wafer 28 to change in gas flow rate (slm) flowing through the corresponding gas flow paths 36A as a function of the distance x from the center of the wafer. For example, examining the layer growth sensitivity function S₁(x) corresponding to the centermost gas flow paths 36AC, it can be seen that the change in gas flow rate in these gas flow paths 36AC has a greater effect on the layer growth rates at areas at distances x that are closer to the center of the wafer. In addition, for example, examining the layer growth sensitivity function S₈(x) corresponding to the outermost gas flow paths 36A, it can be seen that the change in gas flow rate in these gas flow paths 36A has a greater effect on areas near the periphery of the wafer than on areas near the center of the wafer, and that overall their effect is smaller than that of the central gas flow paths 36AC.

In step S21 shown in FIG. 15, a recurrent calculation described below is carried out based on the layer growth rate deviation ΔGR(x) as shown in FIG. 16 and the layer growth sensitivity functions S₁(x) to S₈(x) for each flow rate regulator 56 (each gas flow path 36A) as shown in FIG. 17, and flow rate adjustment values a₁ to a_{N} for each flow rate regulator 56 (each gas flow path 36A) are calculated.

In other words, for the layer growth rate deviation ΔGR(x) at each sampling point xⱼ, the following equation holds true:

ΔGR(xⱼ)=a₁S₁(xⱼ)+a₂S₂(xⱼ)+a₃S₃(xⱼ)+ . . . +a_{N}S_{N}(xⱼ)

Where there are M sampling points xⱼ (where M>N, for example several tens or so), the above-described equation holds true for M points of j=1 to M. Well-known recurrent calculations are executed using these equations for M, as a result of which flow rate adjustment values a₁ to a_{N} for each flow rate regulator 56 (each gas flow path 36A) that best satisfy the equations for M simultaneously are obtained.

Once the flow rate adjustment values a₁ to a_{N} for each flow rate regulator 56 (gas flow path 36A) are obtained as described above, the control process proceeds to step S22 shown in FIG. 15 and the current flow rate settings for the flow rate regulators 56 (gas flow paths 36A) are adjusted using the flow rate adjustment values a₁ to a_{N} described above. Using flow rate settings adjusted as described above, the uneven layer growth rate 94 shown in FIG. 16 is rectified and a uniform layer growth rate that is closer to the target layer growth rate 96 is obtained.

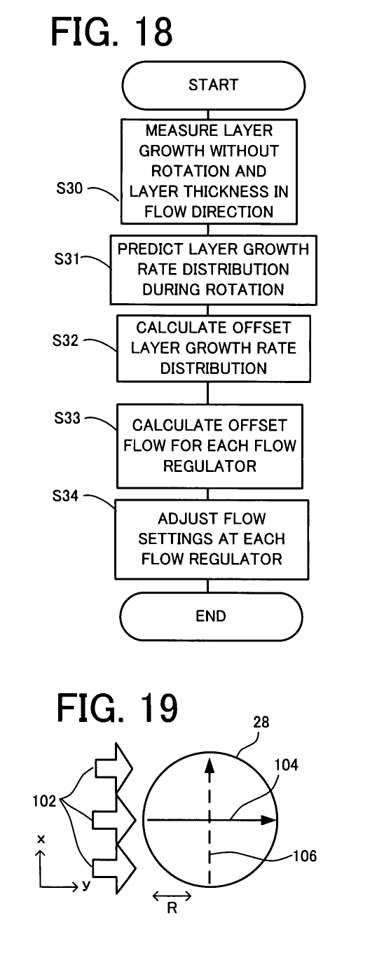

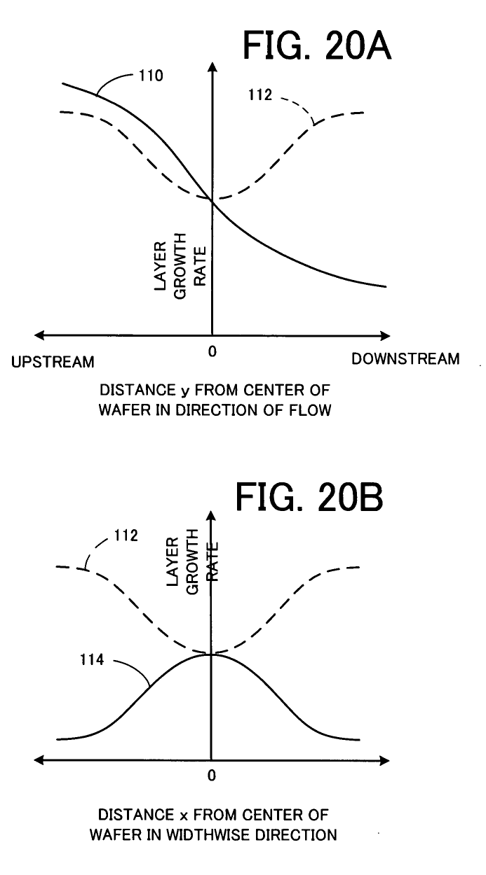

FIG. 18 is a flow chart illustrating a variation of the gas flow rate adjustment control process. FIG. 19 shows a layer thickness measurement direction in the variation of the control process. FIGS. 20A and 20B illustrate specific examples of the variation of the control process.

This variation of the control process is based on the idea that a decline in the concentration of the reactant components in the reactant gas as the reactant gas flow passes over the surface of the wafer 28 inside the reaction chamber 20A is the cause of the unevenness in the layer thickness distribution over the surface of the wafer 28 described above. In other words, the control process of the present variation detects an extent of dilution of the layer deposition components in the direction of the flow of the gas inside the reaction chamber 20A and adjusts the concentration of the reactant gas in a direction that is at a right angle to the flow of gas, that is, in the widthwise direction of the gas inlet port 20B (the gas flow rate distribution), so as to offset that dilution in the direction of flow. The dilution in the direction of gas flow can be offset by the gas flow velocity distribution in the widthwise direction perpendicular thereto (gas flow rate distribution) because the wafer 28 rotates during layer deposition. This variation of the control process may be used together with or in place of the control process shown in FIG. 12, and as a particularly preferably embodiment may be incorporated as an additional flow rate adjustment process stage in the control process shown in FIG. 12, in place of the first stage or the second stage.

In the present variation of the control process, as shown in FIG. 18, in an initial step S30 an experimental layer deposition is carried out using a predetermined initial flow rate setting in a state in which the wafer 28 is held stationary without being rotated. Then, as shown in FIG. 19, the thickness of the layer deposited on the wafer 28 without rotation is measured at various positions in a direction of flow 104 of the gas flow 102. From the layer thickness data obtained by measurement, as shown for example in FIG. 20A a layer growth rate distribution 110 in which the layer growth rate diminishes the farther downstream is calculated.

Thereafter, in step S31 shown in FIG. 18, a predicted layer growth rate distribution assumed to be gotten had the layer been deposited while the wafer 28 was being rotated is calculated based on the layer growth rate distribution 110 of the layer deposited without wafer rotation. For example, as shown in FIG. 20A, by averaging the layer growth rate distribution 110 of the layer deposited without wafer rotation over values at locations that are the same distance from the center of the wafer, a predicted layer growth rate distribution 112 of a layer deposited during wafer rotation is calculated.

Thereafter, in step S32 shown in FIG. 18, a layer growth rate distribution in the widthwise direction (the direction 106 perpendicular to the gas flow direction 104 shown in FIG. 19) necessary to offset the predicted layer growth rate distribution 112 of the layer deposited during wafer rotation and make a flat and uniform distribution is calculated. For example, as shown in FIG. 20B, an offset layer growth rate distribution 114 is calculated by inverting the predicted layer growth rate distribution 112 of the layer deposited during wafer rotation using as the axis of inversion a predetermined target layer growth rate (for example, a minimum rate, a maximum rate or an average rate of the predicted layer growth rate distribution 112, or an arbitrary rate value set in advance).

Thereafter, in step S33, based on the offset layer growth rate distribution 114, offset flow rates for offsetting the predicted layer growth rate distribution 112 of the layer deposited during wafer rotation are calculated for each of the flow rate regulators 56 (gas flow paths 36A). The offset flow rates may be calculated as follows: Specifically, referring to FIG. 19, a gas concentration C(x) of a reactant component, at a position a distance x from the center of the wafer in the widthwise direction and at a position at which that reactant component has flowed downstream a distance R in the direction of flow from the upstream edge of the wafer 28, may be expressed by the following equation:

$$C ( x ) = {C}_{0} exp [ - \sqrt{\frac{{k}_{d}}{H \cdot u ( x )}} \cdot R ] \qquad ( 1 )$$

where k_{d} is a reactant rate constant determined by the material of the reactant component, H is the height of the reaction chamber 20A, C₀ is the initial concentration of the reactant component, and u(x) is the gas flow velocity (gas flow rate) at a position a distance x in the widthwise direction.

Accordingly, the layer growth rate GR(x) at a position downstream a distance R in the direction of flow at a distance x in the widthwise direction can be expressed by the following equation:

$$GR ( x ) = {k}_{d} \cdot {C}_{0} exp [ - \sqrt{\frac{{k}_{d}}{H \cdot u ( x )}} \cdot R ] \qquad ( 2 )$$

From the foregoing equation, the gas flow velocity (gas flow rate) u(x) at a distance x in the widthwise direction can be expressed by the following equation:

$$u ( x ) = \frac{{k}_{d}}{H \cdot {R}^{2}} \cdot \frac{1}{{( ln \frac{GR ( y )}{{k}_{d} \cdot {C}_{0}} )}^{2}} = A \cdot \frac{1}{{( ln GR ( y ) )}^{2}} \qquad ( 3 )$$

Here, because u(x) and GR(x) at a position at which X=0 are known (the predicted layer growth rate distribution 112 shown in FIGS. 20A and 20B), A on the right side of the equation can be calculated on the basis thereof. By substituting the growth rate value at a distance x corresponding to the gas flow path 36A of the offset layer growth rate 114 shown in FIG. 20B for the layer growth rate GR(x) in the foregoing equation, the offset flow rate u(x) for each flow rate regulator 56 (gas flow path 36A) can be obtained.

Thereafter, in step S34 shown in FIG. 18, the flow rate settings for each of the flow rate regulators 56 (gas flow paths 36A) are adjusted to become the offset flow rates u(x) obtained in step S33.

While the present invention has been described with reference to the foregoing preferred embodiments, it is to be understood that these preferred embodiments are merely illustrative of the present invention and that the scope of the present invention is not limited thereto. Consequently, it is to be understood that the present invention encompasses all the various other embodiments by which the invention can be implemented.

What is claimed is:

1. A reactor for depositing a layer on a substrate, comprising:
a reaction device having a reaction chamber in which the substrate is placed;
a gas inlet port provided on the reaction device extending over a predetermined range in a widthwise direction along a periphery of the substrate placed inside the reaction chamber for introducing a reactant gas into the reaction chamber;
a plurality of gas flow paths arrayed widthwise on an upstream side of the gas inlet port that communicate with the gas inlet port, each supplying the reactant gas to the gas inlet port at respective gas flow rates; and
a gas flow control device configured to control the respective gas flow rates of the plurality of gas flow paths,
the gas flow paths numbering at least five within a range of one side of the gas inlet port divided in two at the center of the widthwise direction of the predetermined range of the gas inlet port,
a pitch between adjacent gas flow paths being 10 mm or more.

2. The reactor according to claim 1, wherein the pitch between adjacent gas flow paths ranges from substantially 12 mm to substantially 18 mm.

3. The reactor according to claim 1, wherein a difference between a fastest gas flow velocity and a slowest gas flow velocity immediately after exiting the gas inlet port in a range in the widthwise direction of 1 pitch between adjacent gas flow paths is substantially 0.5 m/sec or less.

4. The reactor according to claim 1, wherein the number of gas flow paths is at least eight in the range of one side of the gas inlet port when the substrate measures substantially 200 mm in the widthwise direction thereof.

5. The reactor according to claim 1, wherein the number of gas flow paths is at least 12 in the range of one side of the gas inlet port when the substrate measures substantially 300 mm in the widthwise direction thereof.

6. A reactor for depositing a layer on a substrate, comprising:
a reaction device having a reaction chamber in which the substrate is placed;
a gas inlet port provided on the reaction device extending over a predetermined range in a widthwise direction along a periphery of the substrate placed inside the reaction chamber for introducing a reactant gas into the reaction chamber;
a plurality of gas flow paths arrayed widthwise on an upstream side of the gas inlet port that communicate with the gas inlet port, each supplying the reactant gas to the gas inlet port at respective gas flow rates; and
a gas flow control device configured to control the respective gas flow rates of the plurality of gas flow paths,
the reactor further comprising a flow velocity equalizer configured to equalize a gas flow velocity distribution in the widthwise direction within each of the plurality of gas flow paths.

7. The reactor according to claim 6, wherein the flow velocity equalizer has a plurality of flow rectifying holes that respectively communicate with the plurality of gas flow paths,
the flow rectifying holes comprising long, narrow slits extending in the widthwise direction.

8. A reactor for depositing a layer on a substrate, comprising:
a reaction device having a reaction chamber in which the substrate is placed;
a gas inlet port provided on the reaction device extending over a predetermined range in a widthwise direction along a periphery of the substrate placed inside the reaction chamber for introducing a reactant gas into the reaction chamber;
a plurality of gas flow paths arrayed widthwise on an upstream side of the gas inlet port that communicate with the gas inlet port, each supplying the reactant gas to the gas inlet port at respective gas flow rates; and
a gas flow control device configured to control the respective gas flow rates of the plurality of gas flow paths,
the reactor further comprising a blade unit disposed inside the gas inlet port having a plurality of blades for forming a plurality of gas transport channels that respectively communicate with the plurality of gas flow paths,
the blade unit comprising a separate component detachable from a component that forms walls of the gas inlet port.

9. A reactor for depositing a layer on a substrate, comprising:
a reaction device having a reaction chamber in which the substrate is placed;
a gas inlet port provided on the reaction device extending over a predetermined range in a widthwise direction along a periphery of the substrate placed inside the reaction chamber for introducing a reactant gas into the reaction chamber;
a plurality of gas flow paths arrayed widthwise on an upstream side of the gas inlet port that communicate with the gas inlet port, each supplying the reactant gas to the gas inlet port at respective gas flow rates; and
a gas flow control device configured to control the respective gas flow rates of the plurality of gas flow paths,
the reactor further comprising a blade unit disposed inside the gas inlet port having a plurality of blades for forming a plurality of gas transport channels that respectively communicate with the plurality of gas flow paths,
a gas flow adjustor unit provided in a gas transport channel located at the center of the blade unit in the widthwise direction thereof for bending gas flows toward the center of the widthwise direction.

10. A reactor for depositing a layer on a substrate, comprising:
a reaction device having a reaction chamber in which the substrate is placed;
a rotation device that rotates the substrate inside the reaction chamber;
a gas inlet port provided on the reaction device extending over a predetermined range in a widthwise direction along a periphery of the substrate placed inside the reaction chamber for introducing a reactant gas into the reaction chamber;
a plurality of gas flow paths arrayed widthwise on an upstream side of the gas inlet port that communicate with the gas inlet port, each supplying the reactant gas to the gas inlet port at respective gas flow rates; and
a gas flow control device configured to control the respective gas flow rates of the plurality of gas flow paths,
the gas flow control device having a first flow rate adjustment means configured to adjust the respective gas flow rates of the plurality of gas flow paths by inputting first layer thickness data indicating a thickness of a first layer previously deposited by rotation on a first substrate while rotating the first substrate inside the reaction chamber, obtaining a deviation between layer growth rates at various locations on the first substrate and a predetermined target layer growth rate based on the first layer thickness data, and using predetermined layer growth sensitivity data that defines a sensitivity to a change in layer growth rate distribution on the substrate caused by a change in the respective gas flow rates of the plurality of gas flow paths to reduce the deviation between the layer growth rates at the various locations on the first substrate and the target layer growth rate.

11. The reactor according to claim 6, wherein the gas flow control device further comprises a second flow rate adjustment means configured to adjust the respective gas flow rates of the plurality of gas flow paths by inputting second layer thickness data indicating a thickness of a second layer previously deposited by rotation on a second substrate while rotating the second substrate inside the reaction chamber and obtaining a convexity slope of the layer thickness distribution on the second substrate to reduce the convexity slope to substantially zero.

12. The reactor according to claim 11, wherein, after the second flow rate adjustment means performs gross adjustment of the gas flow rates, the first flow rate adjustment means inputs the first layer thickness data obtained from results of the first layer previously deposited by rotation applying the gas flow rate as adjusted by the second flow rate adjustment means and further performs fine adjustment of the gas flow rates based on the first layer thickness data.

13. The reactor according to claim 10, wherein the gas flow control device further comprises a third flow rate adjustment means configured to adjust the respective gas flow rates of the plurality of gas flow paths by inputting third layer thickness data indicating a thickness of a third layer previously deposited by non-rotation on a third substrate while holding the third substrate stationary without rotation inside the reaction chamber, obtaining a predicted layer growth rate distribution on the third substrate predicted as if obtained had the layer been deposited by rotation based on the third layer thickness data, and offsetting the predicted layer growth rate.

14. A flow rate control device configured to control a flow rate of a reactant gas supplied to a reactor for depositing a layer on a substrate, the reactor comprising:
a reaction device having a reaction chamber in which the substrate is placed;
a gas inlet port provided on the reaction device extending over a predetermined range in a widthwise direction along a periphery of the substrate placed inside the reaction chamber for introducing a reactant gas into the reaction chamber; and
a plurality of gas flow paths arrayed widthwise on an upstream side of the gas inlet port that communicate with the gas inlet port, each supplying the reactant gas to the gas inlet port at respective gas flow rates,
the gas flow control device adjusting the respective gas flow rates of the plurality of gas flow paths by inputting layer thickness data indicating a thickness of a layer previously deposited by rotation on a substrate while rotating the substrate inside the reaction chamber, obtaining a deviation between layer growth rates at various locations on the substrate and a predetermined target layer growth rate based on the layer thickness data, and using predetermined layer growth sensitivity data that defines a sensitivity to a change in layer growth rate distribution on the substrate caused by a change in the respective gas flow rates of the plurality of gas flow paths to reduce the deviation between the layer growth rates at the various locations on the substrate and the target layer growth rate.

15. A method for depositing a layer on a substrate, comprising:
a gas flow step of rotating a substrate and flowing a reactant gas over a surface of the rotating substrate; and
a gas flow rate adjustment step of adjusting the gas flow rates of a plurality of gas flow paths for controlling a gas flow velocity distribution laterally across the reactant gas flow,
the gas flow rate adjustment step comprising:
obtaining layer thickness data indicating a thickness of a layer previously deposited by rotation on a substrate while rotating the substrate inside the reaction chamber;
obtaining a deviation between layer growth rates at various locations on the first substrate and a predetermined target layer growth rate based on the layer thickness data; and
using predetermined layer growth sensitivity data that defines a sensitivity to a change in layer growth rate distribution on the substrate caused by a change in the respective gas flow rates of the plurality of gas flow paths to reduce the deviation between the layer growth rates at the various locations on the substrate and the target layer growth rate.
